(19) United States
(12) Patent Application Publication
(10) Pub. No.: US 2005/0059255 A1
(43) Pub. Date: Mar. 17, 2005

(54) Wafer processing techniques with enhanced alignment

(75) Inventors: Lawrence John Varnerin III, Mechanicsville, VA (US); Zhijian Lu, Plano, TX (US); Qiang Wu, Poughkeepsie, NY (US)

Correspondence Address: LERNER, DAVID, LITTENBERG,;KRUMHOLZ & MENTLIK, 600 SOUTH AVENUE WEST, WESTFIELD, NJ, 07090, US

(73) Assignees: Infineon Technologies North America Corp., San Jose, CA (US); International Business Machines, Armonk, NY (US)

(21) Appl. No.: 10/661,248

(22) Filed: Sep. 12, 2003

(51) Int. Cl. H01L 21/302; H01L 21/461

(52) U.S. Cl. 438/720

(57) ABSTRACT

A wafer having a top surface including a first material such as silicon dioxide or silicon nitride and a second material such as polysilicon or copper is etched so as to leave elements formed from the second material projecting above the surrounding surface defined by the first material. An opaque layer may be applied over the newly-formed top surface covered by a transparent layer such as a photoresist. The opaque layer has raised features corresponding to the projecting features formed from the second material. These raised features provide contrast and allow an optical system to locate the wafer as, for example, in registering the wafer in a wafer stepper. Alternatively, transparent layers such as an oxide dielectric and a photoresist may be applied after etching. The projecting elements formed by etching remain visible through the transparent layers and similarly allow optical location.

### BACKGROUND OF THE INVENTION

The present invention relates to the art of processing semiconductor wafers.

Semiconductor devices are commonly fabricated in the form of wafers using a series of steps to deposit various materials in successive layers onto a planar wafer surface. The deposited layers typically are etched or otherwise treated using masks formed by depositing a layer of photoresist on the surface of a newly-deposited layer and then exposing the photoresist to light using an apparatus referred to as a “wafer stepper,” so that the light impinges on the photoresist in a pattern corresponding to an image of the desired mask. The photoresist is then subjected to a development process which forms the mask. Depending upon the type of resist, the mask may have cured photoresist in areas which were exposed to light and openings in areas which were not exposed, or vice-versa. The wafer is then subjected to an etching process which attacks the uppermost, most recently deposited layer of the wafer in the openings of the mask, so as to remove that layer in areas of the wafer corresponding to the openings. The mask is then removed, leaving portions of the uppermost layer as features on the wafer surface. Subsequent layers can then be applied, and the process can be repeated. It is essential to form the mask used in each layer in precise registration with the previously-formed features on the wafer, so that the features formed by etching through the mask will lie in the desired position relative to the previously-formed features. For this purpose, the wafer stepper is equipped with optoelectronic detectors which can detect features which are already in place on the wafer. By detecting existing features, the pattern projected by the wafer stepper can be brought into the desired registration with the existing features. For example, a wafer stepper may include an illuminator for projecting light and a device such as an electronic camera for receiving light reflected from the wafer. The camera effectively looks through the layer of photoresist and detects light reflected from existing features of the wafer.

In many semiconductor processing operations, however, the wafer surface is polished after forming a layer of features. For example, a structure known as a “damascene” structure is formed in a wafer having a layer of silicon dioxide (SiO₂) at its top surface. Trenches or other depressions are formed in the wafer structure, and copper or other metal is deposited to fill these depressions. After the metal is deposited, the wafer is polished as, for example, by a process known as chemical mechanical polishing. The resulting structure has a flat top surface. Portions of the top surface are defined by the SiO₂ layer, whereas other portions are defined by the metal features. Typically, the metal features include both the metal features desired as active components of the devices to be formed from the wafer and additional features referred to as alignment marks, which will be detected by the wafer stepper. In the next step of the process, a layer of metal is deposited over the top surface and etched using a photoresist mask formed on the top surface of the newly-deposited metal layer. The newly-deposited metal layer covers the metal features in the depressions, including the alignment marks. The covered alignment marks are invisible to the detector of the wafer stepper. The detector of the wafer stepper cannot reliably find the alignment marks through the metal layer and the photoresist.

Similarly, in formation of some semiconductor devices, polycrystalline silicon or “polysilicon” may be deposited into depressions in a semiconductor structure which incorporates a layer of a silicon nitride dielectric. This structure is subjected to chemical mechanical polishing or other planarization processing so as to form a perfectly flat top surface, including portions defined by the silicon nitride dielectric and other portions defined by the polysilicon features. Here again, the processes used to form the polysilicon features form both active features to be included in functional parts of the device and alignment features. After planarization of the surface, a layer of an SiO₂ dielectric is applied over the flat surface, together with a thin layer of an anti-reflective coating and a layer of photoresist. The photoresist is patterned so as to form a mask which is then used to etch the oxide dielectric. In theory, the wafer stepper can detect the polysilicon alignment marks because the oxide resist and anti-reflective layers are transparent to the light used to illuminate the wafer for alignment. In practice, however, there is little or no contrast between the polysilicon alignment features and the surrounding nitride surface and, accordingly, the optical detector of the wafer stepper cannot always accurately detect these features. This can lead to misregistration of the mask and, hence, misregistration between the features formed in the oxide layer and the polysilicon features.

Accordingly, prior to the present invention, there have been needs for improved processes which would remedy these drawbacks.

### SUMMARY OF THE INVENTION

One aspect of the present invention provides methods of processing a semiconductor wafer.

A method according to this aspect of the present invention desirably begins with a wafer including a layer of a first material with elements formed from a second material embedded therein. The wafer has a planar top surface which is defined in part by the first material and in part by the elements formed from the second material. A method according to this aspect of the invention desirably includes the step of etching at least a portion of the top surface with an etchant which preferentially attacks the first material so as to form a new top surface. The etching process removes only a relatively small thickness of the first material layer and typically removes less than the entire thickness of the first material layer. After the etching step, the wafer has the elements formed from the second material protruding from surrounding portions of the new top surface by a predetermined protrusion height corresponding to the depth of etching. The method according to this aspect of the invention preferably also includes the step of optically locating raised features on the wafer. These raised features may be the protruding second material elements themselves or raised features overlying the protruding second material elements.

Desirably, the etching process is conducted so as to remove only a very small amount of the first material and, thus, leave the projecting features projecting from the surrounding first material by only a very small amount as, for example, about 20-50 nm. The process, thus, does not introduce gross non-planarity into the structure. Nonetheless, the difference in elevation provided by the protruding elements provides sufficient contrast to allow optical detection. The etching process may be conducted entirely non-selectively, over the entire wafer surface. Alternatively, where the features in the original wafer include alignment marks distinct from the active features, the etching process may be conducted using a mask, so that only that portion of the wafer surface in the vicinity of the alignment marks is etched.

A method according to this aspect of the invention desirably includes the step of depositing one or more additional layers on the new top surface after the etching step. The one or more additional layers may include an opaque layer such as a metal layer of substantially uniform thickness, so that the upper surface of the opaque layer defines raised features overlying the protruding elements. The step of depositing one or more additional layers may also include depositing one or more transparent layers, such as a layer of photoresist, over the opaque lower layer. The step of locating the raised features may include transmitting light to the raised features through the transparent layer or layers. For example, in a copper damascene process, the wafer, at the beginning of the process, may have a planar top surface defined by SiO₂ as the first material with features formed from copper as the second material. The etching step removes a small portion of the SiO₂, leaving copper features projecting above the surrounding the SiO₂. A layer of copper is deposited over this surface. The newly-deposited copper layer has raised features overlying the projecting copper features of the original layer. A transparent photoresist is applied over this copper layer. The raised features of the deposited copper layer can be detected readily by the optical detector of the wafer stepper.

Alternatively, the additional layers deposited after the etching step may all be transparent layers. In this case, the projecting elements formed from the second material themselves constitute raised features which can be detected during the locating step. For example, the original wafer may have a planar surface defined by polysilicon features embedded in a layer of silicon nitride. The etching process is conducted so as to remove a small portion of the nitride layer, leaving polysilicon elements projecting slightly above the plane of the surrounding nitride at the newly-formed top surface. An oxide dielectric, a photoresist and, desirably, an antireflective coating as well are applied over this surface. All of these layers are transparent and, hence, the projecting polysilicon elements can be detected during the subsequent locating step as, for example, by the detection apparatus of a wafer stepper.

These and other objects, features and advantages of the invention will be more readily apparent from the detailed description set forth below, taken in conjunction with the accompanying drawings.

### BRIEF DESCRIPTION OF THE DRAWINGS

FIG. 1 is a fragmentary diagrammatic sectional view depicting a portion of a wafer at the inception of a process according to one embodiment of the invention.

FIGS. 2 and 3 are similar to FIG. 1, but depicting the wafer at later stages during the process.

FIG. 4 is a fragmentary diagrammatic sectional view of the wafer shown in FIG. 1 at a later stage of the process, in conjunction with certain processing equipment.

FIG. 5 is a sectional view depicting the wafer of FIGS. 1-4 at a later stage of processing.

FIG. 6 is a fragmentary diagrammatic sectional view of a wafer in a process according to a further embodiment of the invention.

FIG. 7 is a fragmentary diagrammatic sectional view of the wafer shown in FIG. 5 at a later stage of the process, in conjunction with additional processing equipment.

### DETAILED DESCRIPTION OF THE PREFERRED EMBODIMENT

A process in accordance with one embodiment of the invention begins with a wafer 10 incorporating a substrate 12 with one or more layers 14 thereon. Layers 14 typically include materials such as semiconductors, dielectrics and conductors formed into various functional features (not shown). Wafer 10 has a layer of a first material 16, in this case SiO₂, which, at the inception of the process, lies at the top or exposed side of the wafer, remote from substrate 12. Elements 18, 20 and 22, formed from a second material, in this case, copper, are embedded in the SiO₂ layer 16 and extend entirely through such layer to the underlying semiconductor structure 14. The copper elements 18, 20 and 22, together with the SiO₂ layer 16, cooperatively define a starting top surface 24. Surface 24, at the inception of the process, is flat. Such a flat top surface may be provided by conventional polishing processes as, for example, conventional processes of chemical mechanical polishing which subject the top surface to the combined actions of chemical polishing agents and mechanical abrasion.

The copper elements include functional features 18, which will form operative parts of a circuit in a finished semiconductor chip, and one or more alignment marks 22. The layout of the functional features is governed by the requirements to be met in the finished semiconductor chips, to be produced from the wafer. Alignment mark 22 is depicted as disposed at a location remote from the active features, but can be interspersed with the active features as well. The alignment mark desirably has a size, as measured in the plane of the top surface 24, at least equal to the minimum feature size resolvable by the optical system used to locate the wafer, as discussed below. Alignment mark 22 desirably is produced using the same series of conventional process steps used to fabricate the active features 18 and 20. For example, in conventional processes forming such features, depressions such as trenches and vias are formed in the wafer by etching from the top surface, and these depressions are filled with copper prior to the polishing process used to bring the top surface to a flat condition. Desirably, the depression used to form alignment mark 22 is formed using the same etch mask, and at the same time, as the depressions used to form active features 18 and 20, 30 that the alignment mark 22 inherently lies at a fixed, known position relative to the active features 18 and 20.

In the first step of a process according to one embodiment of the invention, the wafer is exposed to an etchant which preferentially attacks the SiO₂ first material. That is, the etchant removes the first material or SiO₂ of layer 16 at a rate substantially greater than the rate at which the etchant dissolves or removes the second material or copper. For example, liquid phase etchants such as dilute hydrofluoric acid solutions, or gas phase etchants such as fluorine plasmas, can be employed. The etchant is applied to the entire top surface 24 of the wafer. The etching process is continued for only a time sufficient to remove a predetermined amount of the first material or SiO₂ in layer 16. Desirably, the first material is etched to a depth of about 5-100 nm and, preferably, about 20-50 nm. The etching process leaves the new top surface 24′ (FIG. 2) with the elements 18, 20 and 22 formed from the second material projecting above the surrounding portions of the surface defined by the remaining first material layer 16′. The protrusion height H is approximately equal to the etching depth, i.e., typically about 5-100 nm and, more preferably, about 20-50 nm.

In the next step of the process, a first or lower additional layer 30 (FIG. 3) is deposited onto the newly-formed top surface 241. Layer 30 in this embodiment is formed from a metal which may have the same composition as the second-material features 18, 20 and 22, and accordingly layer 30 may be formed from copper. Layer 30 desirably is deposited using a process which applies substantially the same amount of material per unit of projected area of surface are 24′. As used herein, the term “projected area” refers to the area of surface 24′ as seen from a direction normal to the general plane of such surface, i.e., a vertical direction as seen in FIGS. 2 and 3. For example, the material of layer 30 may be applied by sputtering or vapor deposition. Desirably, layer 30 has a thickness T (FIG. 3) which is as near as possible to uniform over the entire wafer surface. Desirably, this thickness is less than about 3 micrometers and, more typically, less than 500 nm, preferably less than 250 nm or substantially less. More preferably, the thickness T desirably is about ten times the protrusion height H of the second-material elements or less, and may be about five times the protrusion height or less. The minimum thickness T is set by the functional requirements of the features to be formed from this material. In the embodiment shown, the lower additional layer 30, having the same composition as the second-material features 18, 20 and 22 and being contiguous with these features, merges into these features so as to form a unitary copper body.

Because layer 30 is of substantially uniform thickness, the layer has raised features 32, 34 and 36 overlying projecting elements 18, 20 and 22. Raised features 32, 34 and 36 project from the surrounding upper surface 38 of additional layer 30. The protrusion H′ of raised features 32, 34 and 36 is substantially equal to the protrusion H of features 18, 20 and 22 formed in the previous step. Thus, H′ desirably is about 5-100 nm and, more preferably, about 20-50 nm. As seen in FIG. 3, each raised feature of layer 30 is aligned with a protruding element 18, 20 and 22 formed from the original starting wafer. The raised feature 32, 34 and 36 may be slightly broader or narrower in horizontal direction parallel to the planes of surfaces 24′ and 38, but this effect desirably is minimal. Moreover, despite any broadening or narrowing, the center of each raised feature 32, 34 and 36 is aligned with the corresponding protruding element. For example, the center of raised feature 36 is precisely aligned in the horizontal direction with the center of alignment mark 22.

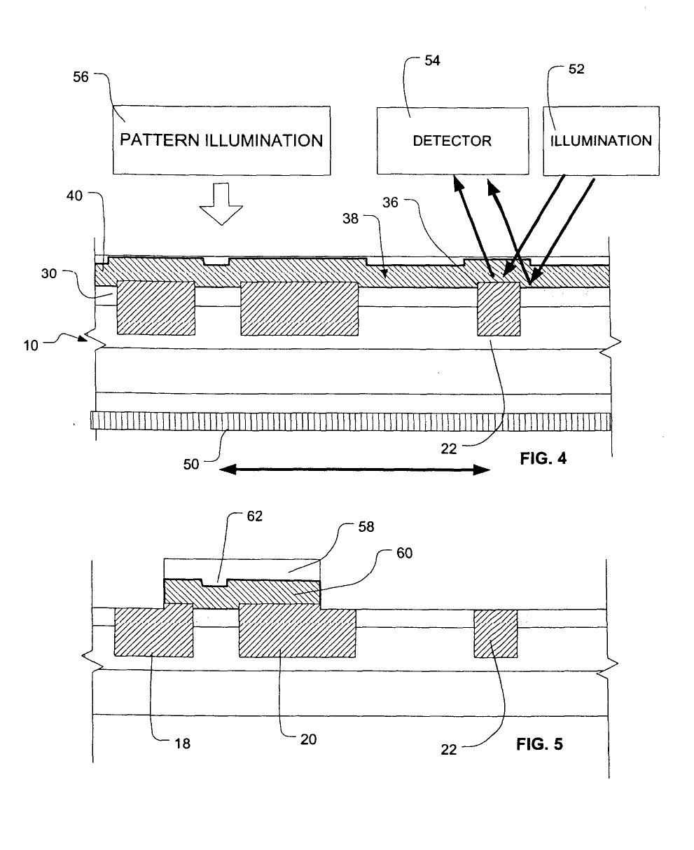

In the next stage of the process (FIG. 4), a second or upper additional layer 40 is deposited over the first or lower additional layer 30. The second layer 40, in this case, consists of a photoresist 40. Photoresist layer 40 desirably is deposited to an average thickness of about 100-1,000 nm and, more preferably, about 200-600 nm. Particularly when the features sizes to be formed are smaller than about 200 nm, the photoresist layer most preferably is about 250-450 nm thick. Layer 40 may be deposited by conventional coating processes, and may include features such as an antireflective coating and hard mask materials. Depending upon the process used to deposit this layer, it may have a substantially flat upper surface, as shown in FIG. 4, or may have irregularities corresponding to the raised features of layer 30.

In the next step of the process, wafer 10 is located in the horizontal plane using one or more of the raised features of layer 30 as a reference. In the example shown, wafer 10 is positioned in a conventional wafer stepper having a stage 50, a broadband visible illumination device or lamp 52 and a detector in the form of a CCD camera 54 associated with conventional pattern recognition elements (not shown). Illumination apparatus 52 is arranged to provide light in a band of wavelengths to which photoresist layer 40 is substantially transparent. Also, the light applied by illumination device 52, at the intensities employed by the illumination device, desirably does not substantially affect the photoresist. Light from the illumination device passes through layer 40 and impinges on the top surface 38 of layer 30. Layer 30 is substantially opaque to this light and substantially reflects the impinging light.

The raised features of layer 30 provide contrast, i.e., bright and dark areas in the light reflected from the surface and seen by detector 54. Accordingly, detector 54 can determine the location of the raised features. Stated another way, detector 54 receives an image including raised feature 36 having some contrast at the edges of the raised feature and, hence, can determine the location of feature 36 relative to the detector. In the embodiment illustrated, the detector 54 determines the location of wafer 10 in horizontal directions, such as the directions to the left and the right and into and out of the plane of the drawing in FIG. 4, based on the image of raised feature 36 corresponding to the original alignment feature 22 of wafer 10 in the light reaching detector 54. Accordingly, the wafer stepper can determine the location of the wafer in the frame of reference of the wafer stepper.

The wafer stepper includes a conventional pattern illumination system 56 as, for example, a system for projecting light in a range of wavelengths adapted to cure the photoresist in layer 40 through a mask (not shown), so that a pattern of light falls at a known location in the frame of reference of the wafer stepper. In the conventional manner, the wafer stepper applies illumination onto the wafer so as to selectively expose portions of photoresist 40. The resist is cured and developed in the conventional manner. Depending on the type of resist, either only the exposed portions or only the unexposed portions remain after curing and development. The remaining portions of the photoresist layer form a mask 58 (FIG. 5) which is used to selectively treat layer 30 as, for example, by etching away portions of the layer not covered by the mask, so as to leave features 60 formed from those portions of the layer which are covered by the mask.

Because the wafer is positioned with reference to raised feature 36 of the lower additional layer 30, which in turn is precisely aligned with the original projecting alignment mark 22 left after the etching step, and because alignment mark 22 is in registration with the other features 18 and 20 formed from the second material, the features 60 formed from layer 30 will be in precise registration with the other second-material elements 18 and 20. In the normal manner, mask 58 is removed and additional layers can be deposited onto the wafer. The features 60 formed from layer 30 may have some non-planarities, as indicated at 62, resulting from the projection of underlying elements 18 and 20, as discussed above. These non-planarities, however, will be on the same order as the projection height of the second-material features H, i.e., typically less than 100 nm and preferably less than 50 nm. Non-planarities of this height typically will not adversely affect processes used to deposit subsequent layers.

Although the description above refers to only a single alignment mark 22, it should be appreciated that, in practice, there are typically numerous alignment features on a wafer. Also, the process of locating the wafer typically is repeated many times over as the wafer stepper exposes various areas of the wafer in sequence.

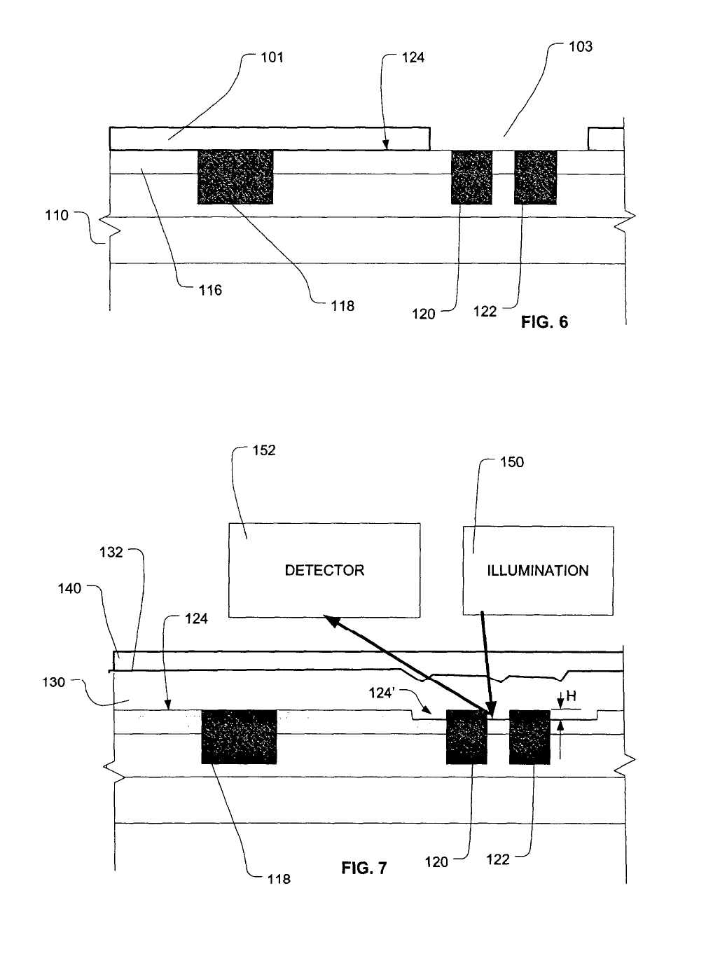

A process in accordance with a further embodiment of the invention begins with a starting wafer 110 (FIG. 6) having a layer 116 of a first material and elements 118, 120, and 122 formed from a second material embedded therein and extending downwardly from the top of the layer into the underlying wafer structure. In this instance, the first material of layer 116 is silicon nitride. The second material in elements 118, 120, and 122 is polysilicon. In this example as well, all of the second-material elements 118, 120 and 122 are formed in a common process (not shown), so that all of these features are in precise registration with one another in the horizontal directions of the wafer. Merely by way of example, element 118 may be a polysilicon-filled trench used in forming a deep trench semiconductor structure. Elements 120 and 122, disposed adjacent one another, will form parts of a diffraction grating alignment feature. In practice, such a grating typically would include more than two elements, but only two are shown for clarity of illustration. Here again, wafer 110 has a flat top surface 124 defined by the first material layer 116 and the second-material elements 118, 120 and 122. For example, flat surface 124 may be a surface resulting from chemical mechanical polishing, lapping or other steps used to planarize the surface.

In a first stage of a process according to this embodiment, a mask 101 having openings 103, of which only one is seen in FIG. 6, is applied onto the top surface. Desirably, each opening 103 has horizontal dimensions substantially larger than the horizontal dimensions of a group of alignment features 120, 122. Therefore, mask 101 need not be precisely aligned with the second-material elements. For example, mask 101 can be registered with the wafer using physical features of the wafer or other relatively crude alignment techniques. Mask 101 may be formed from any material which will block the etching used in the next phase of the process. For example, masks of the type commonly known as KD or KV masks can be used.

Following application of mask 101, the surface 24 exposed within opening 103 is etched by an etching process similar to that discussed above, so as to form a new top surface 124′ (FIG. 7) only in those areas aligned with opening 103 and to leave the original top surface 124 unaltered in the remaining portions of the wafer. Thus, at this stage of the process, the second material elements or polysilicon alignment features 120 and 122 project above the surrounding new surface 124′ defined by the first-material layer. The protrusion height H, again, is equal to the etching depth and may be of the same order as discussed above, i.e., desirably about 5-100 nm and, most preferably, about 20-50 nm. Features 118 in areas of the wafer out of alignment with holes 103 and, hence, covered by mask 101, remain flush with the original top surface 124. After etching, mask 101 is removed.

In the next stage of the process, a transparent dielectric as, for example, silicon dioxide deposited from a gaseous mixture including tetraethyl orthosilicate (TEOS) 130, is deposited as a lower additional layer 130, immediately overlying the composite top surface 124, 124′. Layer 130, for example, may be about 50-500 nm thick, most preferably about 200-400 nm thick as, for example, about 280 nm thick. The top surface 132 of layer 130 may have irregularities overlying the etched region 124 of the original top surface and raised features 120 and 122. An anti-reflective coating (not shown) desirably is deposited on the top surface 132 of oxide layer 130. Also, an upper additional layer 140 formed from a photoresist is deposited over the oxide layer and anti-reflective coating. These deposition processes may be conducted using conventional techniques.

After deposition of the additional layers 130 and 140, the wafer is located in a wafer stepper. The wafer stepper has a laser light source 150 and a detector 150. Source 150 directs light onto the wafer from its front surface, defined by the top additional layer 140. All of the additional layers, including lower additional layer 130 formed from oxide and upper additional layer 140 formed from photoresist, are transparent to the light used to illuminate the wafer during the locating step. The light from illumination source 150 passes through both upper layers and impinges on the surface 124′ formed in the etching step. Thus, the light impinges directly on the projecting elements 120, 122 formed from the second material in the original wafer. These projecting elements, i.e., alignment features 120 and 122, thus act as raised features which interact with the applied illumination. Alignment features 120 and 122 cooperatively act as a diffraction grating. The diffracted light passes back through layers 130, 140 to detector 152. Here again, the raised features or surface relief indicated by the protrusion height H is sufficient for the raised features 120, 122 to act as a diffraction grating and provide an appreciable signal, i.e., a diffraction pattern with appreciable amplitude. This signal is detected by detector 152, and the wafer stepper uses this signal to indicate position of the wafer in horizontal dimensions. In the conventional manner, the wafer stepper applies pattern illumination to selectively activate the photoresist in upper additional layer 140. That photoresist is then cured to form a mask which, once again, is in precise registration with alignment features 120 and 122 and, hence, in precise registration with the other second-material elements such as trench filling 118. For example, the photoresist mask may be used to form openings in the lower additional layer or oxide layer 130, which in turn can be filled by subsequently deposited semiconductor layers or other layers needed to form the desired device structure. In this arrangement, the active second-material element 118 remains exactly co-planar with the surface 124 of the original nitride layer and, hence, the process does not affect the subsequently deposited layers.

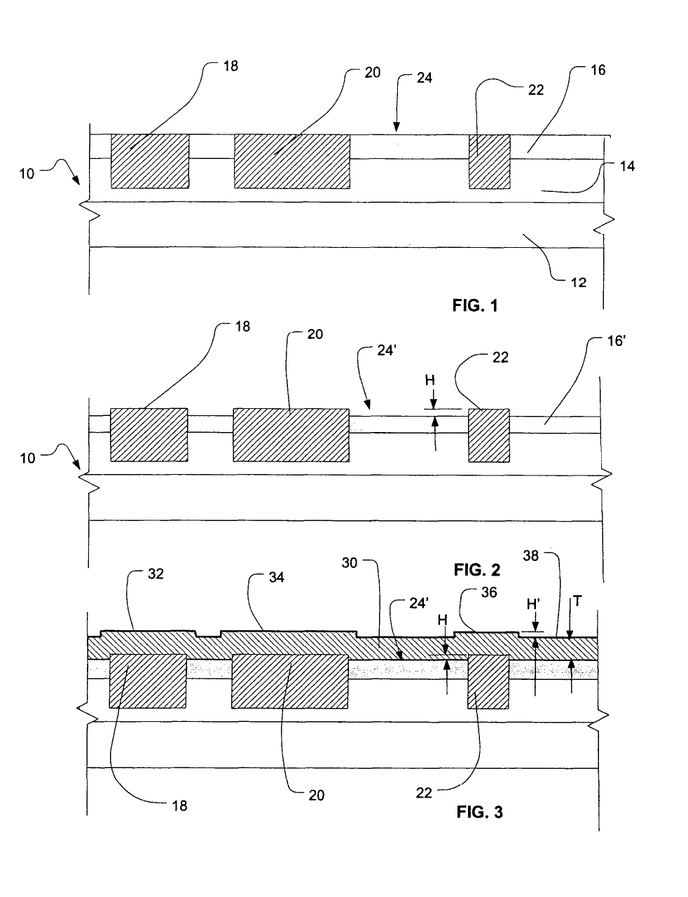

Numerous variations and combinations of the features discussed above can be utilized without departing from the present invention. Merely by way of example, the process of FIGS. 6 and 7 can be performed without using the mask, so that the entire top surface of the original wafer is etched and all of the second-material elements project above the top surface after the etching step. Conversely, a mask such as that used with reference to FIGS. 6 and 7 can be employed in an etching process prior to forming an opaque lower layer such as the copper layer of FIGS. 1-5.

Of course, the process can be applied to wafers having diverse materials and not be limited to conventional silicon wafers. For example, the first and second materials defining the original top surface of the wafer need not include SiO₂ or silicon nitride with polysilicon or copper as discussed above, but can instead include any combination of materials, such that one material can be attacked by an etchant which does not attack the other material, or which attacks the other material at a substantially lower rate. The materials applied in the additional layers, after forming the projecting features by the etching step, may include materials other than the metals, oxides and photoresists discussed above. Moreover, each layer discussed above may include alloys, mixtures and combinations of materials, or may be deposited as a plurality of sub-layers. For example, the metal layer 30 discussed above with reference to FIG. 3 may be constituted by a plurality of sub-layers formed from different metals.

It is not essential to deposit a plurality of additional layers. For example, the etching process can be performed so as to leave the projecting elements, and only a single layer formed from a photoresist may be applied. Here again, the wafer can be located and the photoresist can be selectively exposed to form a mask which can be used in further treatment of the original structure. In yet another variant, no additional layers are applied. Thus, the wafer, with the projecting second-material elements resulting from the etching step, can be located by directing light onto the wafer surface in the manner described above, even if no further layers have been applied. Such a process can be used, for example, during examination of the wafer as, for example, in examination of the wafer using a microscope or other miniaturized sensing device. Also, the further processes applied after location need not include etching. Other selective processes as, for example, selective ion implantation or the like, can be applied.

In a further variant, the first-material layer at the original top surface of said wafer may have a thickness corresponding to the desired etch depth. An etch-stop layer resistant to the etchant may be provided immediately beneath the first-material layer. In this case, the etching step may be conducted to as to entirely remove the first material, leaving the second-material features projecting from surrounding portions of the new top surface defined by the etch-stop layer.

As these and other variations and combinations of the features discussed above can be employed, the foregoing description of the preferred embodiments should be taken by way of illustration rather than by way of limitation of the present invention.

1. A method of processing a semiconductor wafer comprising the steps of:
(a) providing a wafer having a planar top surface defined by a layer of a first material with elements of a second material embedded therein;
(b) etching at least a portion of said top surface with an etchant which preferentially attacks said first material so as form a new top surface with said elements of said second material protruding from surrounding portions of said new top surface; and
(c) optically locating one or more raised features on said wafer defined by said protruding second material elements or overlying said protruding second material elements.

2. The method as claimed in claim 1 further comprising the step of depositing one or more additional layers on said new top surface before said locating step.

3. The method as claimed in claim 2 wherein said step of optically locating said raised features includes directing light through one or more of said additional layers to said raised features and detecting light which has interacted with said raised features.

4. The method as claimed in claim 2 wherein said step of depositing one or more additional layers includes depositing an opaque lower additional layer of substantially uniform thickness so that said lower additional layer defines an upper surface having said raised features overlying the protruding second material elements.

5. The method as claimed in claim 4 wherein said step of depositing one or more additional layers includes the step of depositing one or more transparent layers over said upper surface of said opaque lower additional layer, and wherein said step of directing light includes directing light through said one or more transparent layers to said raised features at said upper surface.

6. A method as claimed in claim 5 wherein said protruding second material elements project above the surrounding portions of said new top surface by a protrusion height of less than about 100 nm.

7. A method as claimed in claim 6 wherein said opaque lower additional layer has a thickness less than about ten times said protrusion height.

8. A method as claimed in claim 6 wherein said protrusion height is between about 20 nm and about 50 nm.

9. A method as claimed in claim 5 wherein said one or more transparent layers includes a layer of a photoresist.

10. A method as claimed in claim 4 wherein said lower additional layer is formed from a metallic material.

11. A method as claimed in claim 10 wherein said second material is metallic and said lower layer is deposited directly on said new top surface of said wafer, so that said metallic lower additional layer is contiguous with said elements formed from said second material.

12. A method as claimed in claim 11 wherein said second material and said metallic material of said lower layer consist essentially of copper.

13. A method as claimed in claim 2 wherein said one or more additional layers consist solely of transparent layers, wherein said raised features are defined by said protruding second material elements and wherein said locating step includes directing light through said transparent layers to said protruding second material elements.

14. A method as claimed in claim 13 wherein said step of depositing one or more additional layers include depositing a transparent dielectric layer and then depositing a layer of a photoresist.

15. A method as claimed in claim 14 wherein said step of depositing one or more additional layers further includes depositing an antireflection coating on said transparent dielectric layer before depositing said photoresist.

16. A method as claimed in claim 14 wherein said transparent dielectric layer includes an oxide.

17. A method as claimed in claim 1 wherein said wafer includes at least one functional region and at least one alignment region, said elements formed from said second material include one or more alignment marks disposed in said at least one alignment region, and said step of etching said top surface is performed only in said at least one alignment region.

18. A method as claimed in claim 1 wherein said step of etching said top surface is performed over the entire top surface.

19. A method as claimed in claim 1 wherein said raised features form a diffraction grating and said step of detecting light includes detecting light diffracted by said grating.

20. A method as claimed in claim 2 wherein said locating step is performed so as to locate the wafer in the frame of reference of a processing apparatus, the method further comprising forming additional features on the wafer at least in part by operation of said processing apparatus.

21. A method as claimed in claim 20 wherein said processing apparatus is a wafer stepper and said step of forming additional features includes applying patterned illumination to the wafer.

22. A method of processing a semiconductor wafer comprising the steps of:
(a) providing a starting wafer including a top layer of dielectric with metallic damascene elements therein, said layer having a planar top surface, said dielectric and said damascene elements being exposed at said top surface;
(b) etching said top surface with an etchant which preferentially attacks said dielectric so as to form a new top surface with said damascene elements protruding from said dielectric; and
(c) depositing a metallic layer of substantially uniform thickness on said top surface so that said metallic layer defines an upper surface having raised features overlying said damascene elements projecting.

23. A method as claimed in claim 22 further comprising the steps of locating said raised features and registering the wafer with processing apparatus based on the detected locations.

24. A method as claimed in claim 22 further comprising the step of depositing a photoresist layer over said metallic layer before said locating step, said step of locating including directing light through said photoresist layer.

25. A method as claimed in claim 22 wherein said step of providing a starting wafer includes chemical mechanical polishing.

26. A method as claimed in claim 22 wherein said step of etching said top surface includes exposing said damascene features and said dielectric at said top surface to an etchant non-selectively, over the entire top surface of the wafer.

27. A method as claimed in claim 22 wherein said starting wafer includes at least one functional region and at least one alignment region, said damascene elements include alignment marks disposed in said at least one alignment region and functional damascene elements in said at least one functional region, said step of etching said top surface is performed in said at least one alignment region but not in said at least one functional region.

28. A method as claimed in claim 22 wherein said dielectric includes SiO₂ at said top surface.

29. A method as claimed in claim 28 wherein said damascene features include copper.

30. A method as claimed in claim 29 wherein said etching step includes exposing said top surface to an etchant selected from the group consisting of hydrofluoric acid solutions and fluorine-containing plasmas.

31. A method as claimed in claim 22 wherein said step of etching said top surface is performed so as to leave said damascene features protruding above said dielectric by 20 to 50 nm.

32. A method as claimed in claim 31 further comprising the step of depositing a photoresist layer between 100 nm and 1 μm thick over said metallic layer before said locating step, said step of locating including directing light through said photoresist layer

33. A method as claimed in claim 32 wherein said metallic layer is less than about 500 nm thick.

34. A method of processing a semiconductor wafer comprising the steps of:
(a) providing a starting wafer including a top layer of dielectric with polysilicon elements therein, said layer having a planar top surface, said dielectric and said polysilicon elements being exposed at said top surface;
(b) etching said top surface with an etchant which preferentially attacks said dielectric so as to leave said top surface with said polysilicon elements protruding from said dielectric; and
(c) depositing a transparent oxide layer on said top surface so that said polysilicon elements project into said oxide layer; and then
(d) locating said polysilicon elements by directing light through said oxide layer and detecting light which has interacted with said polysilicon elements, and registering the wafer with processing equipment based at least in part upon the locations of the polysilicon elements.

35. A method as claimed in claim 34 further comprising the step of depositing a photoresist over said transparent oxide layer before said locating step.

36. A method as claimed in claim 34 wherein said polysilicon elements protrude above said nitride dielectric layer by a protrusion height less than about 100 nm.
